(19) United States
(12) Patent Application Publication
(10) Pub. No.: US 2025/0298086 A1
(43) Pub. Date: Sep. 25, 2025

(54) LITHIUM-METAL-BATTERY DEGRADATION-STATE DETERMINATION DEVICE, METHOD OF DETERMINING DEGRADATION STATE OF LITHIUM METAL BATTERY, AND STORAGE MEDIUM

(71) Applicant: HONDA MOTOR CO., LTD., Tokyo (JP)

(72) Inventors: Pu Qian, Wako-shi (JP); Wataru Hoshikawa, Wako-shi (JP); Takaharu Watanabe, Wako-shi (JP); Kota Ogasawara, Wako-shi (JP); Shiori Nakanishi, Wako-shi (JP)

(21) Appl. No.: 19/058,045

(22) Filed: Feb. 20, 2025

(30) Foreign Application Priority Data
Mar. 22, 2024 (JP) 2024-047172

(51) Int. Cl. G01R 31/392; G01R 31/367; G01R 31/389; H01M 10/0525

(52) U.S. Cl. CPC G01R 31/392; G01R 31/367; G01R 31/389; H01M 10/0525

(57) ABSTRACT

A lithium-metal-battery degradation-state determination device includes a processor. The processor is configured to acquire resistance value information relating to a resistance value obtained by applying a voltage to a lithium metal battery including a negative electrode containing lithium, and determine a degradation state of the lithium metal battery based on a first map, created in advance and indicating a relationship between a thickness of the negative electrode and the resistance value, and the acquired resistance value information.

### CROSS-REFERENCE TO RELATED APPLICATION

Priority is claimed on Japanese Patent Application No. 2024-047172, filed Mar. 22, 2024, the content of which is incorporated herein by reference.

### BACKGROUND OF THE INVENTION

### Field of the Invention

The present invention relates to a lithium-metal-battery degradation-state determination device, a method of determining a degradation state of a lithium metal battery, and a storage medium.

### Description of Related Art

In recent years, in order to ensure that more people can have access to affordable, reliable, sustainable, and advanced energy, research and development has been conducted to contribute to energy efficiency (for example, see PCT International Publication No. WO 2023/118960, Japanese Unexamined Patent Application, First Publication No. 2023-17581, and Japanese Unexamined Patent Application, First Publication No. 2022-113377). With regard to such a technology, lithium metal batteries using lithium metal for a negative electrode have attracted attention as a secondary battery. A lithium metal battery includes a positive electrode, a negative electrode having a metallic lithium layer, and an electrolyte disposed between the positive electrode and the negative electrode.

Incidentally, in a lithium metal battery of the present technology, as charging and discharging is repeated, a solid electrolyte interphase (SEI) film is formed and grows on a metallic lithium layer of the negative electrode. Therefore, as a thickness of the negative electrode increases, a load is applied to the lithium metal due to the increase in thickness of the negative electrode, raising concerns about degradation that could result in structural damage or the like to the lithium metal battery.

The invention has been made in consideration of such circumstances, and an object thereof is to detect degradation of a lithium metal battery with high accuracy. Furthermore, this contributes to energy efficiency.

### SUMMARY OF THE INVENTION

A lithium-metal-battery degradation-state determination device, a method of determining a degradation state of a lithium metal battery, and a storage medium according to the invention employ the following configuration.
(1) A lithium-metal-battery degradation-state determination device according to one aspect of the invention includes a processor. The processor is configured to: acquire resistance value information relating to a resistance value obtained by applying a voltage to a lithium metal battery including a negative electrode containing lithium; and determine a degradation state of the lithium metal battery based on a first map, created in advance and indicating a relationship between a thickness of the negative electrode and the resistance value, and the acquired resistance value information.
(2) In the aspect of the above-described (1), the processor is configured to acquire the resistance value information based on a current value of a current discharged from the lithium metal battery.
(3) In the aspect of the above-described (1), the processor is configured to determine that the degradation state of the lithium metal battery is a reusable state when the acquired resistance value is a resistance value at which a thickness of the negative electrode is less than or equal to a first reference value.
(4) In the aspect of the above-described (3), the processor is configured to: determine a degradation state of the lithium metal battery further based on a second map created in advance and indicating a relationship between a thickness of a positive electrode of the lithium metal battery and the resistance value; and determine that the degradation state of the lithium metal battery is a reusable state when the acquired resistance value is a resistance value at which a thickness of the positive electrode is less than or equal to a second reference value.
(5, 6) In the aspect of the above-described (3) or (4), the lithium metal battery is a lithium metal battery mounted in a vehicle, and the processor is configured to acquire a resistance value obtained by applying an AC voltage to the lithium metal battery removed from the vehicle.
(7) In the aspect of the above-described (1), the lithium metal battery is a lithium metal battery mounted in a vehicle, and the processor is configured to acquire a resistance value obtained by applying an AC voltage to the lithium metal battery mounted in the vehicle.
(8) In the aspect of the above-described (1), the lithium metal battery is a lithium metal battery mounted in a vehicle, the processor is configured to: acquire a measurement result obtained by measuring a current discharged from the lithium metal battery at a timing after a predetermined time period of 0.001 to 1.0 seconds has elapsed for the lithium metal battery mounted in the vehicle; and acquire a preliminary determination result obtained by preliminarily determining a degradation state of the lithium metal battery based on the measurement result. The determination unit is configured to preliminarily determine the degradation state of the lithium metal battery based on the preliminary determination result obtained by preliminarily determining the degradation state of the lithium metal battery based on the acquired measurement result.
(9) A method of determining a degradation state of a lithium metal battery according to one aspect of the invention causes a computer to: acquire resistance value information relating to a resistance value obtained by applying a voltage to a lithium metal battery including a negative electrode containing lithium, and determine a degradation state of the lithium metal battery based on a first map, created in advance and indicating a relationship between a thickness of the negative electrode and the resistance value, and the acquired resistance value information.
(10) A storage medium according to one aspect of the invention is a computer-readable non-transitory storage medium storing a program. The program causes a computer to: acquire resistance value information relating to a resistance value obtained by applying a voltage to a lithium metal battery including a negative electrode containing lithium; and determine a degradation state of the lithium metal battery based on a first map, created in advance and indicating a relationship between a thickness of the negative electrode and the resistance value, and the acquired resistance value information.

According to the aspects (1) to (10), degradation of the lithium metal battery can be detected with high accuracy.

### BRIEF DESCRIPTION OF THE DRAWINGS

FIG. 1 is a block diagram showing an example of a degradation state determination device 100 of a first embodiment.

FIG. 2 is a diagram showing an example of a state in which a lithium metal battery 10 is mounted in a vehicle M.

FIG. 3 is a view schematically showing a change in a negative electrode 12 when the lithium metal battery 10 is repeatedly charged and discharged.

FIG. 4 is a diagram showing an example of a visualized degradation determination map 121.

FIG. 5 is a diagram showing an example of a visualized preliminary determination map 122.

FIG. 6 is a flowchart showing an example of processing of the determination device 100 of the first embodiment.

FIG. 7 is a block diagram showing an example of a degradation state determination device 200 of a second embodiment.

FIG. 8 is a diagram showing an example of a visualized both electrode degradation determination map 123.

FIG. 9 is a flowchart showing an example of processing of a determination device 200 of the second embodiment.

FIG. 10 is a graph showing an example of a relationship between an impedance mainly derived from a resistance value and an impedance mainly derived from a capacitive component.

### DETAILED DESCRIPTION OF THE INVENTION

Hereinafter, embodiments of a lithium-metal-battery degradation-state determination device, a method of determining a degradation state of a lithium metal battery, and a storage medium of the invention will be described with reference to the drawings.

### First Embodiment

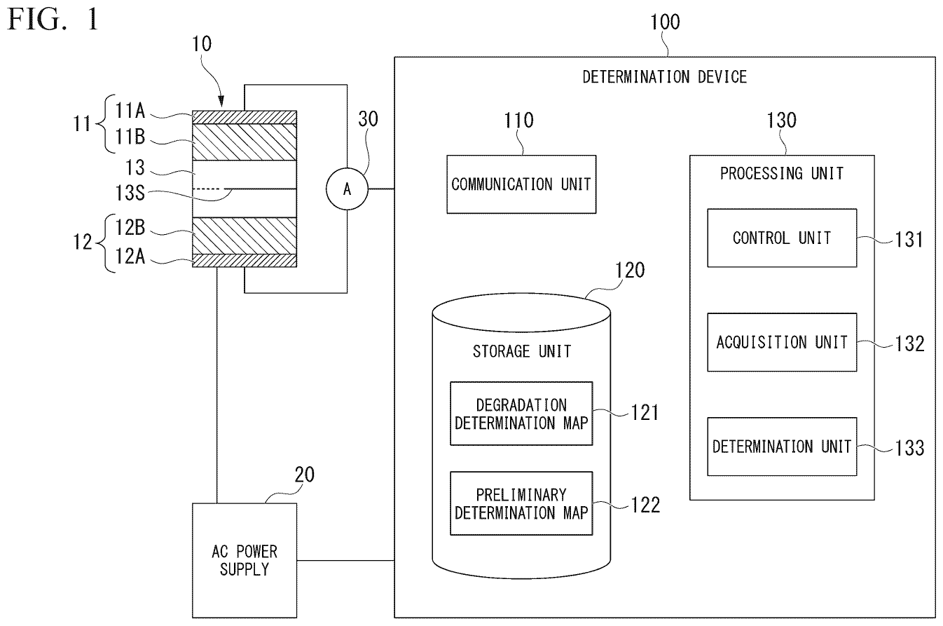

A first embodiment will be described. FIG. 1 is a block diagram showing an example of a degradation state determination device 100 of the first embodiment. The degradation state determination device (hereinafter, determination device) 100 of the first embodiment determines a degradation state of a lithium metal battery 10. The lithium metal battery 10 includes a negative electrode containing lithium. The lithium metal battery 10 is a secondary battery that is capable of being charged and discharged. The lithium metal battery 10 is, for example, mounted in a vehicle for use.

For example, after the in-vehicle lithium metal battery 10 is removed from the vehicle, the determination device 100 determines a degradation state of the lithium metal battery 10, and determines whether a degree of degradation of the lithium metal battery 10 is sufficient for reuse. When a degradation state of the lithium metal battery 10 is determined by the determination device 100, the lithium metal battery 10 is connected to an AC power supply 20 and an ammeter 30. The degradation state of the lithium metal battery 10 determined by the determination device 100 is mainly a state related to structural damage of the lithium metal battery 10 based on growth of an SEI layer adhering to the negative electrode.

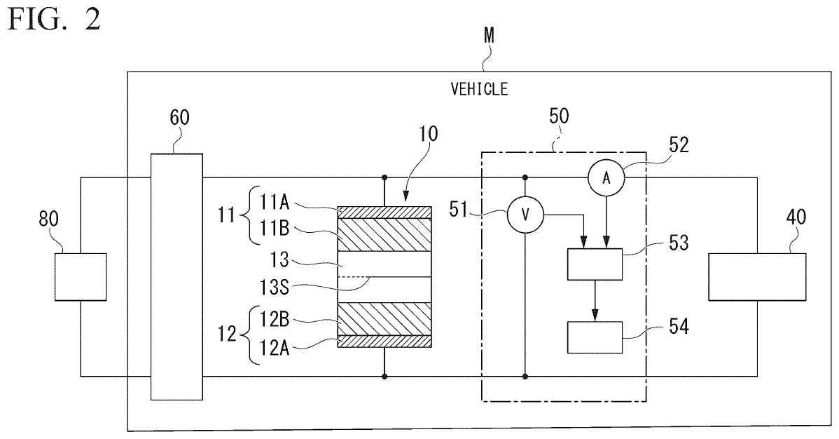

Prior to describing the determination device 100, the lithium metal battery 10 will be described. FIG. 2 is a diagram showing an example of a state in which the lithium metal battery 10 is mounted in a vehicle M. Electrical equipment 40, a preliminary degradation measurement device 50, and a converter 60 are mounted in the vehicle M in addition to the lithium metal battery 10. In the vehicle M, the preliminary degradation measurement device 50 preliminarily measures degradation of the lithium metal battery 10 when the vehicle M supplies power to the electrical equipment 40 using the lithium metal battery 10.

The lithium metal battery 10 is, for example, a semi-solid-state battery. The lithium metal battery 10 includes, for example, a positive electrode 11, a negative electrode 12, and an electrolyte 13. The positive electrode 11 includes, for example, a positive electrode current collector 11A and a positive electrode active material layer 11B. The positive electrode current collector 11A is formed of, for example, a current collector foil such as aluminum. The positive electrode active material layer 11B is formed of, for example, a layer such as that of lithium cobalt oxide.

The negative electrode 12 includes, for example, a negative electrode current collector 12A and a negative electrode active material layer 12B. The negative electrode current collector 12A is formed of, for example, a current collector foil such as copper. The negative electrode active material layer 12B is formed of, for example, a metallic lithium layer. The electrolyte 13 is a semi-solid electrolyte containing lithium ions Li+. The electrolyte 13 is partitioned into the side of the positive electrode 11 and the side of the negative electrode 12 by a separator 13S.

During discharge, when the lithium metal battery 10 supplies power to the electrical equipment 40 mounted in the vehicle M, the lithium ions Li+ flow from the negative electrode active material layer 12B to the positive electrode 11 through the separator 13S. Along with the flow of lithium ions Li+, electrons e flow from the negative electrode 12 to the positive electrode 11 through a circuit of the electrical equipment 40. Due to the flow of lithium ions Li+ and electrons e, a current flows from the side of the positive electrode 11 to the side of the negative electrode 12, and the lithium metal battery 10 is discharged. In the negative electrode active material layer 12B, metallic lithium dissolves as the lithium metal battery 10 is discharged.

The lithium metal battery 10 is charged by a charging facility 80 external to the vehicle M. The charging facility 80 is provided, for example, at a home of the owner of the vehicle M owner, a charging station, or the like. During charging, lithium ions Li+ flow from the positive electrode active material layer 11B to the side of the negative electrode 12 through the separator 13S.

Along with the flow of lithium ions Li+, electrons e flow from the positive electrode 11 to the side of the negative electrode 12 through the charging facility 80. Due to the flow of lithium ions Li+ and electrons e, a current flows from the side of the negative electrode 12 to the side of the positive electrode 11, and the lithium metal battery 10 is charged. In the negative electrode active material layer 12B, metallic lithium is deposited as the lithium metal battery 10 is charged.

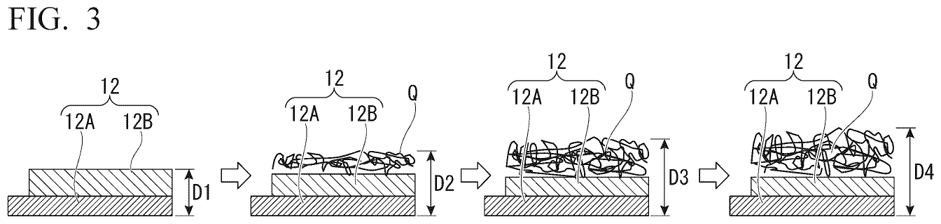

FIG. 3 is a view schematically showing a change in the negative electrode 12 when the lithium metal battery 10 is repeatedly charged and discharged. As the lithium metal battery 10 is repeatedly charged and discharged, metallic lithium is deposited on the negative electrode active material layer 12B. As a result, along with the passage of time, an SEI layer Q gradually thickens as a form of degradation of the lithium metal battery 10, and a thickness of the negative electrode 12 gradually increases from a first thickness D1 to a second thickness D2, a third thickness D3, and a fourth thickness D4.

The electrical equipment 40 is mounted in the vehicle M and includes various devices to which power is supplied by the lithium metal battery 10. The electrical equipment 40 includes, for example, a driving motor that causes the vehicle M to travel, an air conditioning control device that controls an air conditioning in a vehicle interior of the vehicle M, and a monitor that displays images to provide various information to an occupant.

The preliminary degradation measurement device 50 includes, for example, a voltage detector 51, a current detector 52, an arithmetic device 53, and a providing device. The voltage detector 51 detects a voltage value between terminals of the lithium metal battery 10. The current detector 52 detects a current value of a current flowing from the side of the positive electrode 11 to the side of the negative electrode 12 of the lithium metal battery 10.

The arithmetic device 53 estimates a degree of growth of an SEI film of the lithium metal layer in the lithium metal battery 10 based on the voltage value detected by the voltage detector 51 and the current value detected by the current detector 52. In estimating the degree of growth of the SEI film, the arithmetic device 53 measures a current discharged from the lithium metal battery 10 mounted in the vehicle M at a timing after a predetermined time period of 0.001 to 1.0 seconds, for example 0.1 seconds, has elapsed.

The arithmetic device 53 measures, for example, a voltage drop after 0.1 seconds based on the voltage value output by the voltage detector 51. The arithmetic device 53 further measures a current after 0.1 seconds based on the current value output from the current detector 52. The arithmetic device 53 calculates an impedance after 0.1 seconds (hereinafter referred to as a 0.1 second resistance) based on the measured voltage drop after 0.1 seconds and the current after 0.1 seconds. Specifically, the arithmetic device 53 calculates the 0.1 second resistance as a value obtained by dividing the voltage drop after 0.1 seconds by the current after 0.1 seconds. The 0.1 second resistance increases as the number of charge/discharge cycles of the lithium metal battery 10 increases.

The providing device 54 stores the 0.1 second resistance calculated by the arithmetic device 53. When the lithium metal battery 10 is removed from the vehicle M and connected to the determination device 100, the providing device 54 provides some or all of the stored 0.1 second resistance, for example, the latest value of the 0.1 second resistance to the determination device 100.

Returning to FIG. 1, the AC power supply 20 applies a test voltage to the lithium metal battery 10 under a control of the determination device 100. The test voltage is applied to the lithium metal battery 10 as, for example, an alternating current. The ammeter 30 is connected to the lithium metal battery 10. The ammeter 30 measures, for example, a current value of the current discharged from the lithium metal battery 10 to which the test voltage is applied by the AC power supply 20. The ammeter 30 transmits a current signal based on the measured current value to the determination device 100.

The determination device 100 includes, for example, a communication unit 110, a storage unit 120, and a processing unit 130. The communication unit 110 transmits and receives signals between the determination device 100 and an external device. The communication unit 110 transmits, for example, a current supply signal generated by the processing unit 130 to the AC power supply 20. The communication unit 110 receives the current signal transmitted by the ammeter 30. The transmission and reception performed by the communication unit 110 may be wired communication via wiring or wireless communication via a network.

The storage unit 120 is formed of, for example, a hard disk drive (HDD) or a flash memory. The storage unit 120 stores a degradation determination map 121 and a preliminary determination map 122. The degradation determination map 121 is a map that shows a relationship between a thickness of the negative electrode 12 and a resistance value of the lithium metal battery 10, and is a map that is created in advance.

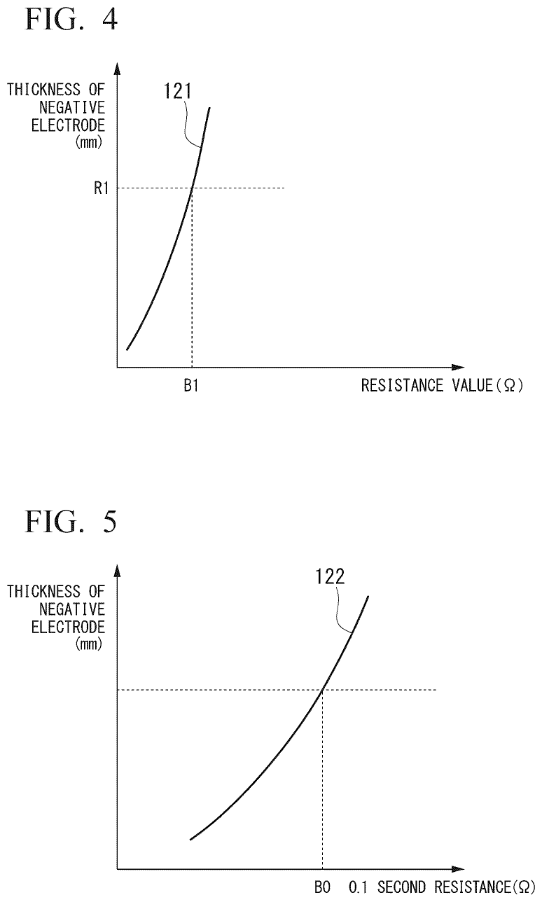

FIG. 4 is a diagram showing an example of the visualized degradation determination map 121. The degradation determination map 121 is obtained by, for example, the following method. Specifically, in the method of obtaining the map, first, the 0.1 second resistance or an AC impedance is measured when an AC voltage is applied to the lithium metal battery 10 produced for testing and having a known thickness of the negative electrode 12. Second, a bulk resistance and a negative electrode reaction resistance are determined, and then a resistance value for the thickness of the negative electrode 12 is determined.

The degradation determination map 121 may be created using a lithium metal battery in which a thickness of the negative electrode 12 is unknown. In this case, the degradation determination map 121 may be generated by measuring the thickness of the negative electrode 12 when an AC voltage is applied to the lithium metal battery 10, and using a resistance value calculated when the AC voltage is applied to the lithium metal battery 10. The degradation determination map 121 is an example of a first map.

A first reference value B1, which serves as a criterion for determining whether or not degradation of the lithium metal battery 10 has progressed to a point at which the lithium metal battery 10 is not reusable, is set in the degradation determination map 121. The first reference value B1 is, for example, a resistance value corresponding to the thickness of the negative electrode 12 at which growth of the SEI layer formed on the negative electrode 12 has progressed and it is determined that the lithium metal battery 10 has a high likelihood of suffering structural damage.

The preliminary determination map 122 is, for example, a map that shows a relationship between a thickness of the negative electrode 12 and a resistance value of the 0.1 second resistance, and is a map that is created in advance. FIG. 5 is a diagram showing an example of the visualized preliminary determination map 122. The preliminary determination map 122 is calculated, for example, using a resistance value calculated based on a current value of the current discharged from the lithium metal battery 10 having a known thickness of the negative electrode 12. The preliminary determination map 122 may be generated by measuring the thickness of the negative electrode 12 when a current is discharged from the lithium metal battery 10 and utilizing the resistance value calculated based on the current value of the current discharged from the lithium metal battery 10.

A preliminary reference value B0, which serves as a criterion for preliminary determining whether or not degradation of the lithium metal battery 10 has progressed to a point at which the lithium metal battery 10 is not reusable, is set in the preliminary determination map 122. The preliminary reference value B0 is, for example, a resistance value corresponding to the thickness of the negative electrode 12 at which growth of the SEI layer formed on the negative electrode 12 has progressed and it is determined that the lithium metal battery 10 has a likelihood of suffering structural damage. The preliminary reference value B0 is a value larger than the first reference value B1.

The processing unit 130 includes, for example, a control unit 131, an acquisition unit 132, and a determination unit 133. These components are realized by, for example, a hardware processor such as a central processing unit (CPU) executing a program (software). Some or all of these components may be realized by hardware (circuit unit including a circuitry) such as a large scale integration (LSI), an application specific integrated circuit (ASIC), a field-programmable gate array (FPGA), and a graphics processing unit (GPU), or may be realized by software and hardware in cooperation.

The program may be stored in the storage unit 120 (a storage device having a non-transitory storage medium) such as an HDD or a flash memory in advance, or may be stored in a detachable storage medium (non-transitory storage medium) such as a DVD or a CD-ROM and installed when the storage medium is loaded into a drive device.

The control unit 131 comprehensively controls an operation of the determination device 100 when, for example, the determination device 100 determines a degradation state of the lithium metal battery 10. For example, when determination of the degradation state of the lithium metal battery 10 is started, the control unit 131 generates a current supply signal for applying a predetermined AC voltage to the lithium metal battery 10 as a test voltage and transmits it to the AC power supply 20.

The acquisition unit 132 acquires resistance value information relating to a resistance value obtained by applying a voltage to the lithium metal battery 10. The acquisition unit 132 acquires, for example, a current signal transmitted by the ammeter 30 and received by the communication unit 110. The acquisition unit 132 acquires, based on the acquired current signal, a current value of the current discharged by the lithium metal battery 10 to which the test voltage has been applied.

The acquisition unit 132 calculates the resistance value of the lithium metal battery 10 based on the acquired current value and a voltage value of the voltage applied to the lithium metal battery 10 by the AC power supply 20. The acquisition unit 132 calculates the resistance value of the lithium metal battery 10 by, for example, dividing the acquired current value by the voltage value of the voltage applied to the lithium metal battery 10. The acquisition unit 132 acquires the calculated resistance value as resistance value information. The acquisition unit 132 further acquires information on the 0.1 second resistance of the lithium metal battery 10 provided by the providing device 54 as a preliminary determination result obtained by preliminarily determining the lithium metal battery 10.

The determination unit 133 determines a degradation state of the lithium metal battery 10 based on the degradation determination map 121 and the resistance value information acquired by the acquisition unit 132. The determination unit 133 calculates a thickness of the negative electrode 12 in the lithium metal battery 10 by, for example, referring to the degradation determination map 121 for the resistance value based on the acquired resistance value information. The determination unit 133 compares the calculated thickness of the negative electrode 12 with the first reference value B1 to determine the degradation state of the lithium metal battery 10.

Before comparing the thickness of the negative electrode 12 with the first reference value B1 to determine the degradation state of the lithium metal battery 10, preliminary determination is carried out by the determination unit 133. Specifically, the determination unit 133 preliminarily determines the degradation state of the lithium metal battery 10 based on the 0.1 second resistance provided by the providing device 54 of the lithium metal battery 10 and acquired by the acquisition unit 132, and the preliminary determination map 122. The determination unit 133, for example, refers to the 0.1 second resistance in the preliminary determination map 122 and compares the 0.1 second resistance with the preliminary reference value B0 to preliminarily determine the degradation state of the lithium metal battery 10.

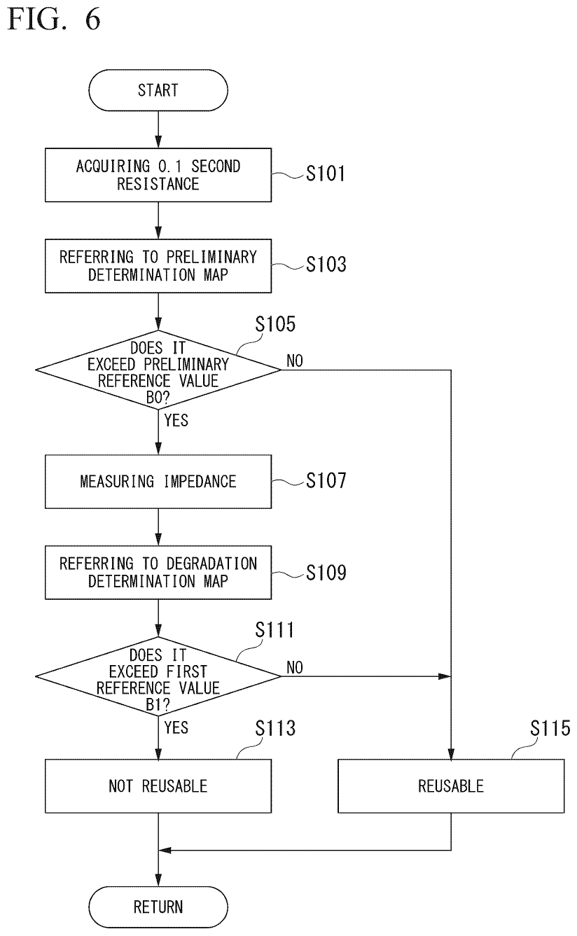

Next, processing by the determination device 100 of the first embodiment will be described. FIG. 6 is a flowchart showing an example of processing of the determination device 100 of the first embodiment. The flowchart shown in FIG. 6 is executed after the lithium metal battery 10 that has been removed from the vehicle M is connected to the determination device 100.

First, the determination device 100 acquires the latest 0.1 second resistance of the lithium metal battery 10 provided by the providing device 54 at the acquisition unit 132 (step S101). Next, the determination unit 133 refers to the 0.1 second resistance acquired by the acquisition unit 132 in the preliminary determination map 122 (step S103), and determines whether the acquired 0.1 second resistance exceeds the preliminary reference value B0 (step S105).

When the determination unit 133 determines that the acquired 0.1 second resistance exceeds the preliminary reference value B0, the determination device 100 performs impedance measurement (step S107) and acquires the resistance value of the lithium metal battery 10. In the impedance measurement, first, the control unit 131 transmits a current supply signal to the AC power supply 20. When the AC power supply 20 that has received the current supply signal applies a test voltage to the lithium metal battery 10, the ammeter 30 measures a current value of the current discharged from the lithium metal battery 10, generates a current signal based on the current value, and transmits it to the determination device 100.

The determination device 100 acquires the current signal transmitted by the ammeter 30 at the acquisition unit 132. Next, the acquisition unit 132 calculates the resistance value of the lithium metal battery 10 based on the current value based on the acquired current signal and the voltage value of the voltage applied to the lithium metal battery 10 by the AC power supply 20, thereby acquiring the resistance value information. In this manner, the impedance measurement is performed.

Next, the determination unit 133 refers to the degradation determination map 121 for the resistance value based on the resistance value information acquired by the acquisition unit 132 (step S109), and determines whether the resistance value of the lithium metal battery 10 exceeds the first reference value B1 (step S111). When the resistance value of the lithium metal battery 10 is determined to exceed the first reference value B1, the determination unit 133 determines that the lithium metal battery 10 is not reusable (step S113). In this manner, the determination device 100 ends the processing shown in FIG. 6.

In step S105, if the determination unit 133 determines that the acquired 0.1 second resistance does not exceed the preliminary reference value B0 (is less than or equal to the preliminary reference value B0), the determination unit 133 determines that reuse is possible (step S115), and the determination device 100 ends the processing shown in FIG. 6. Also, even if it is determined in step S111 that the resistance value of the lithium metal battery 10 does not exceed the first reference value B1 (is less than or equal to the first reference value B1), the determination unit 133 determines that reuse is possible (step S115), and the determination device 100 ends the processing shown in FIG. 6.

The determination device 100 of the first embodiment determines degradation of the lithium metal battery 10 using the degradation determination map 121. Therefore, degradation of the lithium metal battery 10 can be determined with high accuracy. Further, when the lithium metal battery 10 is removed from the vehicle, the determination device 100 of the first embodiment determines degradation for the lithium metal battery 10 that has been preliminarily determined to be degraded based on the 0.1 second resistance, and determines whether or not it can be reused. Therefore, since the determination of degradation for the lithium metal battery 10 with a low likelihood of being reusable can be omitted, it becomes possible to efficiently determine whether or not the lithium metal batteries 10 can be reused.

### Second Embodiment

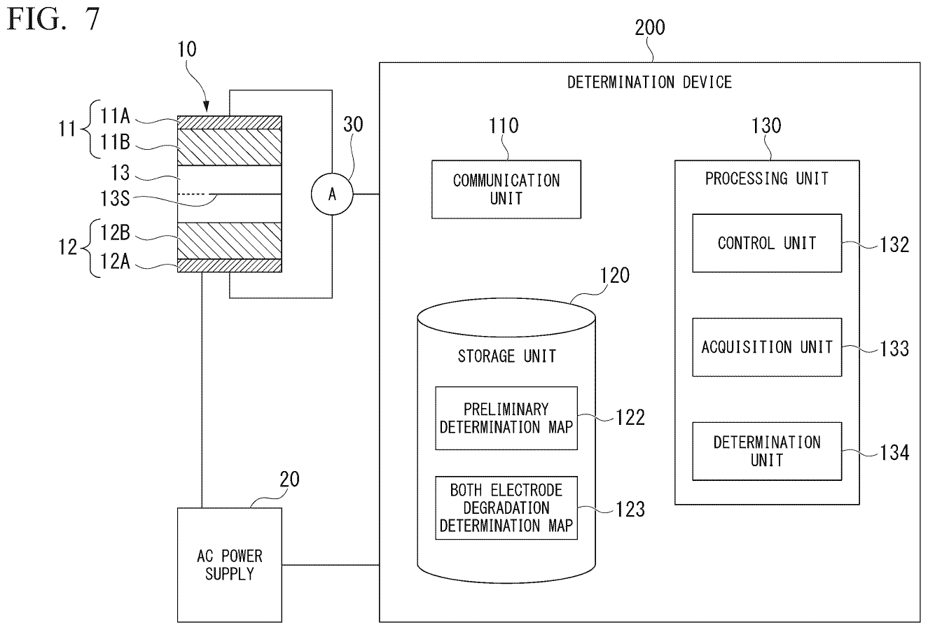

Next, a second embodiment will be described. FIG. 7 is a block diagram showing an example of a determination device 200 of the second embodiment. The second embodiment is different from the first embodiment mainly in that a both electrode degradation determination map 123 is stored in a storage unit 120 and in a process utilizing the both electrode degradation determination map 123. In the following description, elements common to those in the first embodiment will be denoted by the same reference signs, and description thereof will be omitted.

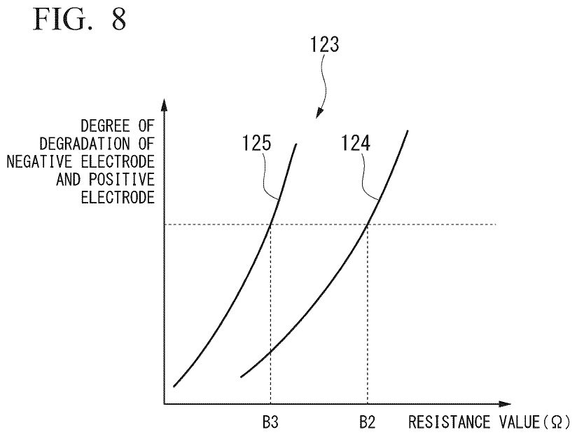

In a determination device 200 of the second embodiment, the storage unit 120 stores the both electrode degradation determination map 123 instead of the degradation determination map 121. The both electrode degradation determination map 123 is a map indicating a relationship between degrees of degradation of a positive electrode 11 and a negative electrode and a resistance value of a lithium metal battery 10, and is a map that is created in advance. FIG. 8 is a diagram showing an example of the visualized both electrode degradation determination map 123.

The both electrode degradation determination map 123 is generated by, for example, using a resistance value calculated when an AC voltage is applied to the lithium metal battery 10 with known degradation degrees of the positive electrode 11 and the negative electrode. A degree of degradation of the positive electrode 11 appears, for example, as a change between layers of the positive electrode 11, and as degradation of the positive electrode 11 progresses, a thickness of the positive electrode 11 increases, resulting in an increase in resistance value of the lithium metal battery 10. A degree of degradation of a negative electrode 12 is determined by, for example, using a thickness of the negative electrode 12 in the first embodiment.

The both electrode degradation determination map 123 includes a positive electrode degradation determination map 124 and a negative electrode degradation determination map 125. The positive electrode degradation determination map 124 is a map obtained by, for example, measuring the 0.1 second resistance or AC impedance of the lithium metal battery 10, determining a bulk resistance and a positive electrode reaction resistance respectively, and determining a resistance value with respect to a thickness of the positive electrode 11. The negative electrode degradation determination map 125 is a map similar to the degradation determination map 121 in the first embodiment. The positive electrode degradation determination map 124 is an example of a second map.

A second reference value B2 and a third reference value B3, which serve as criteria for determining whether the lithium metal battery 10 is no longer reusable after degradation of the lithium metal battery 10 has progressed, are respectively set in the positive electrode degradation determination map 124 and the negative electrode degradation determination map 125. The second reference value B2 is, for example, a resistance value corresponding to a thickness of the positive electrode 11 at which it is determined that degradation of the positive electrode 11 has progressed and the lithium metal battery 10 has a high likelihood of not being reusable. The third reference value B3 is, for example, a value corresponding to the first reference value B1 in the first embodiment.

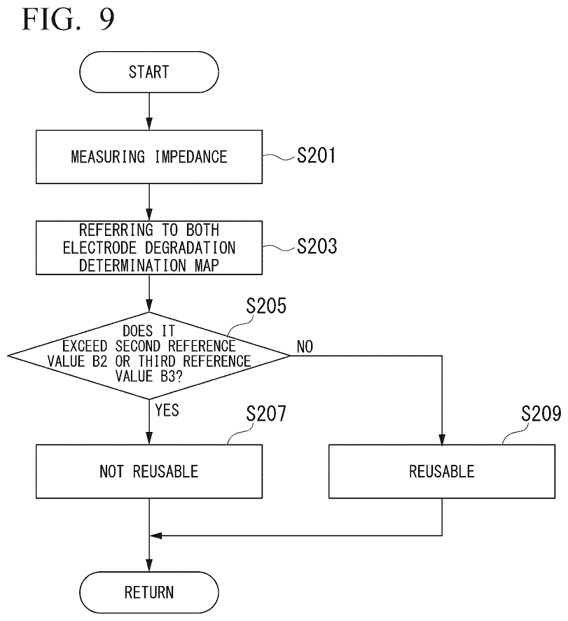

Next, processing by the determination device 200 of the second embodiment will be described. FIG. 9 is a flowchart showing an example of processing by the determination device 200 of the second embodiment. The flowchart shown in FIG. 9 is executed, for example, after it is determined that the preliminary reference value has been exceeded in the progressing up to step S105 shown in FIG. 6 in the first embodiment.

The determination device 200 first performs impedance measurement (step S201) to obtain the resistance value of the lithium metal battery 10. In the impedance measurement, an ammeter 30 measures a current value of a current discharged from the lithium metal battery 10 in the same procedure as in the first embodiment, generates a current signal based on the current value, and transmits it to the determination device 100. The determination device 100 calculates the resistance value of the lithium metal battery 10 in the same procedure as in the first embodiment, and acquires resistance value information.

Next, the determination unit 133 refers to the both electrode degradation determination map 123 for the resistance value based on the resistance value information acquired by an acquisition unit 132 (step S203), and determines whether the resistance value of the lithium metal battery 10 exceeds the second reference value B2 or the third reference value B3 (step S205). When it is determined that the resistance value of the lithium metal battery 10 exceeds the second reference value B2 or the third reference value B3, the determination unit 133 determines that reuse of the lithium metal battery 10 is not possible (step S207). In this manner, the determination device 200 ends the processing shown in FIG. 9. If it is determined that the resistance value of the lithium metal battery 10 does not exceed either the second reference value B2 or the third reference value B3 (is less than or equal to the second reference value B2 and the third reference value B3), the determination unit 133 determines that reuse of the lithium metal battery 10 is possible (step S209). In this manner, the determination device 100 ends the processing shown in FIG. 9.

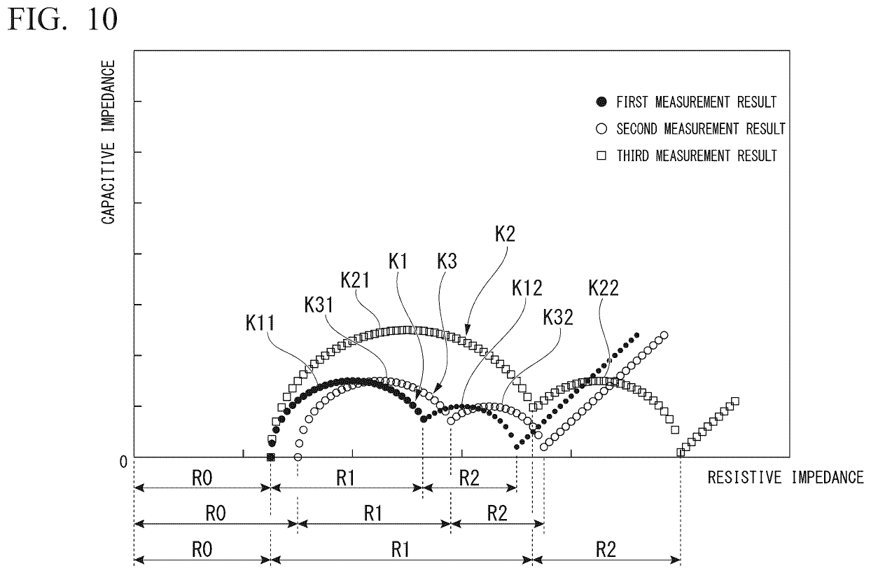

Here, a procedure for determining the bulk resistance, the negative electrode reaction resistance, and the positive electrode reaction resistance used when the both electrode degradation determination map 123 is generated will be described. FIG. 10 is a graph showing an example of a relationship between an impedance mainly derived from a resistance value and an impedance mainly derived from a capacitive component. In FIG. 10, the horizontal axis indicates an impedance mainly derived from the resistance value, and the vertical axis indicates an impedance mainly derived from the capacitive component.

FIG. 10 shows a relationship between an impedance derived from the measured resistance value (hereinafter, resistive impedance) and an impedance derived mainly from the capacitive component (hereinafter, capacitive impedance) for three lithium metal batteries 10. The measurement results for the three lithium metal batteries 10 are shown as a first measurement result, a second measurement result, and a third measurement result.

In all of a first capacitor curve K1, a second capacitor curve K2, and a third capacitor curve K3, which respectively indicate the first measurement result, the second measurement result, and the third measurement result, the capacitive impedance is zero before an AC voltage is applied to the lithium metal battery 10. From that state, when an AC voltage is applied to the lithium metal battery 10, both the resistive impedance and the capacitive impedance increase.

In an initial stage of applying an AC voltage to the lithium metal battery 10, as the resistive impedance increases, the capacitive impedance also increases, but once the resistive impedance reaches a first peak, the relationship shifts to one in which the capacitive impedance decreases as the resistive impedance increases. Further, when the resistive impedance reaches a first lowest point, the relationship returns to one in which the capacitive impedance increases as the resistive impedance increases. Therefore, first arc lines K11, K21, and K31 with their first rise forming a convex shape are generated in the first capacitor curve K1, the second capacitor curve K2, and the third capacitor curve K3.

Then, when the resistive impedance reaches a second peak, again, the relationship becomes such that the capacitive impedance decreases as the resistive impedance increases. Further, when the resistive impedance reaches a second lowest point, thereafter, the relationship becomes such that the capacitive impedance increases as the resistive impedance increases. Therefore, second arc lines K12, K22, and K32 with their first rise forming a convex shape are generated in the first capacitor curve K1, the second capacitor curve K2, and the third capacitor curve K3. If there is no capacitive component in the lithium metal battery 10, the first capacitor curve K1, all of the second capacitor curve K2, and the third capacitor curve K3 will be linear.

Since a capacitive component is present in the lithium metal battery 10, the first arc lines K11, K21, and K31 and the second arc lines K12, K22, and K32 are respectively generated in the first capacitor curve K1, the second capacitor curve K2, and the third capacitor curve K3. In the first capacitor curve K1, the second capacitor curve K2, and the third capacitor curve K3, left end points of the first arc lines K11, K21, and K31 are each considered to be a bulk resistance R0.

Also, lengths (resistive impedances) of the first arc lines K11, K21, and K31 are each considered to be a negative electrode reaction resistance R1 which is generated mainly by an influence of the negative electrode 12. Also, lengths of the second arc lines K12, K22, and K32 are each considered to be a positive electrode reaction resistance R2 which is generated mainly by an influence of the positive electrode 11. Theoretically, the 0.1 second resistance is obtained by adding the bulk resistance R0, the negative electrode reaction resistance R1, and the positive electrode reaction resistance R2.

The determination device 200 of the second embodiment achieves the same operation and effects as those of the first embodiment. The determination device 200 of the second embodiment further determines degradation of the lithium metal battery 10 by additionally using the both electrode degradation determination map 123 including the positive electrode degradation determination map 124 and the negative electrode degradation determination map 125. Therefore, the degradation of the lithium metal battery 10 can be determined with higher accuracy.

In each of the above-described embodiments, the degradation state of the lithium metal battery 10 after the lithium metal battery 10 has been removed from the vehicle M is determined, but the degradation state of the lithium metal battery 10 may also be determined by connecting the determination device 100 or 200 to the lithium metal battery 10 mounted in the vehicle M. In this case, an AC voltage is applied to the lithium metal battery 10 mounted in the vehicle M.

When a voltage is applied to the lithium metal battery 10 to determine the degradation state of the lithium metal battery 10, the AC power supply 20 may be used, or a voltage supplied by the charging facility 80 shown in FIG. 2 may be used. When the voltage supplied by the charging facility 80 is used, the converter 60 may supply an AC voltage to the lithium metal battery 10 by reducing the AC voltage supplied to the charging facility 80 while keeping it as AC.

Also, for the lithium metal battery 10 that has been determined to be reusable, a remaining lifespan when the lithium metal battery 10 is reused may be estimated based on the measured thickness of the negative electrode 12. In this case, the remaining lifespan of the lithium metal battery 10 may be reduced as the thickness of the negative electrode 12 increases. If there are the lithium metal batteries 10 that have been determined to be reusable, and when a plurality of lithium metal batteries 10 are to be used in combination, the lithium metal batteries 10 having similar remaining lifespans may be combined.

The above-described embodiments can be expressed as follows.

A lithium-metal-battery degradation-state determination device includes: a storage medium storing computer-readable instructions; and a processor connected to the storage medium.

The processor is configured to execute the computer-readable instructions to:
acquire resistance value information relating to a resistance value obtained by applying a voltage to a lithium metal battery including a negative electrode containing lithium, and
determine a degradation state of the lithium metal battery based on a first map, created in advance and indicating a relationship between a thickness of the negative electrode and the resistance value, and the acquired resistance value information.

While preferred embodiments of the invention have been described and illustrated above, it should be understood that these are exemplary of the invention and are not to be considered as limiting. Additions, omissions, substitutions, and other modifications can be made without departing from the spirit or scope of the invention. Accordingly, the invention is not to be considered as being limited by the foregoing description, and is only limited by the scope of the appended claims.

What is claimed is:

1. A lithium-metal-battery degradation-state determination device comprising a processor, the processor being configured to:
acquire resistance value information relating to a resistance value obtained by applying a voltage to a lithium metal battery including a negative electrode containing lithium, and
determine a degradation state of the lithium metal battery based on a first map, created in advance and indicating a relationship between a thickness of the negative electrode and the resistance value, and the acquired resistance value information.

2. The lithium-metal-battery degradation-state determination device according to claim 1, wherein
the processor is configured to acquire the resistance value information based on a current value of a current discharged from the lithium metal battery.

3. The lithium-metal-battery degradation-state determination device according to claim 1, wherein
the processor is configured to determine that the degradation state of the lithium metal battery is a reusable state when the acquired resistance value is a resistance value at which a thickness of the negative electrode is less than or equal to a first reference value.

4. The lithium-metal-battery degradation-state determination device according to claim 3, wherein
the processor is configured to:
determine a degradation state of the lithium metal battery further based on a second map created in advance and indicating a relationship between a thickness of a positive electrode of the lithium metal battery and the resistance value; and
determine that the degradation state of the lithium metal battery is a reusable state when the acquired resistance value is a resistance value at which a thickness of the positive electrode is less than or equal to a second reference value.

5. The lithium-metal-battery degradation-state determination device according to claim 3, wherein
the lithium metal battery is a lithium metal battery mounted in a vehicle, and
the processor is configured to acquire a resistance value obtained by applying an AC voltage to the lithium metal battery removed from the vehicle.

6. The lithium-metal-battery degradation-state determination device according to claim 4, wherein
the lithium metal battery is a lithium metal battery mounted in a vehicle, and
the processor is configured to acquire a resistance value obtained by applying an AC voltage to the lithium metal battery removed from the vehicle.

7. The lithium-metal-battery degradation-state determination device according to claim 1, wherein
the lithium metal battery is a lithium metal battery mounted in a vehicle, and
the processor is configured to acquire a resistance value obtained by applying an AC voltage to the lithium metal battery mounted in the vehicle.

8. The lithium-metal-battery degradation-state determination device according to claim 1, wherein
the lithium metal battery is a lithium metal battery mounted in a vehicle,
the processor is configured to:
acquire a measurement result obtained by measuring a current discharged from the lithium metal battery at a timing after a predetermined time period of 0.001 to 1.0 seconds has elapsed for the lithium metal battery mounted in the vehicle; and
acquire a preliminary determination result obtained by preliminarily determining a degradation state of the lithium metal battery based on the measurement result, and
the determination unit is configured to preliminarily determine the degradation state of the lithium metal battery based on the preliminary determination result obtained by preliminarily determining the degradation state of the lithium metal battery based on the acquired measurement result.

9. A method of determining a degradation state of a lithium metal battery, the method causing a computer to:
acquire resistance value information relating to a resistance value obtained by applying a voltage to a lithium metal battery including a negative electrode containing lithium, and
determine a degradation state of the lithium metal battery based on a first map, created in advance and indicating a relationship between a thickness of the negative electrode and the resistance value, and the acquired resistance value information.

10. A computer-readable non-transitory storage medium storing a program, the program causing a computer to:
acquire resistance value information relating to a resistance value obtained by applying a voltage to a lithium metal battery including a negative electrode containing lithium, and
determine a degradation state of the lithium metal battery based on a first map, created in advance and indicating a relationship between a thickness of the negative electrode and the resistance value, and the acquired resistance value information.
